(19) United States
(12) Patent Application Publication
(10) Pub. No.: US 2023/0008638 A1
(43) Pub. Date: Jan. 12, 2023

(54) COMPOSITE QUANTUM-DOT OPTICAL FILM AND THE METHOD TO MAKE THE SAME

(71) Applicant: UBRIGHT OPTRONICS CORPORATION, Taoyuan City (TW)

(72) Inventors: Chia-Yeh Miu, Taoyuan City (TW); Ge-Wei Lin, Taoyuan City (TW); Lung-Pin Hsin, Taoyuan City (TW); Jeffrey Wu, Taoyuan City (TW); Hui-Yong Chen, Taoyuan City (TW); Yu-Mei Juan, Taoyuan City (TW)

(21) Appl. No.: 17/859,021

(22) Filed: Jul. 7, 2022

Related U.S. Application Data
(60) Provisional application No. 63/218,931, filed on Jul. 7, 2021.

(51) Int. Cl. H01L 51/50; H01L 51/00; C09K 11/02; C09K 11/54

(52) U.S. Cl. CPC H01L 51/502; H01L 51/0041; H01L 51/004; C09K 11/02; C09K 11/54; H01L 2251/556

(57) ABSTRACT

A composite quantum-dot optical film comprises a quantum-dot layer and a composite structure disposed on the quantum-dot layer, wherein the composite structure comprises a first substrate, a second substrate, and a first barrier layer, wherein each of the first substrate and the second substrate comprises a polymer material, wherein the barrier layer being made of organic material and capable of being water-resistant is disposed between the first substrate and the second substrate.

### CROSS-REFERENCE TO RELATED APPLICATIONS

This application claims the benefit of U.S. provisional patent application No. 63/218,931, filed on Jul. 7, 2021, which is hereby incorporated herein by reference.

### BACKGROUND OF THE INVENTION

### 1. Field of the Invention

The present invention relates to an optical film, and more particularly to a composite quantum-dot optical film.

### 2. Description of Related Art

The quantum dot is a semiconductor particle having a nanometer size and a spherical shape. The colored spectrum can be generated when the quantum dots are excited by light or electricity. The color of the excited light is determined according to the material and the size of the quantum dot. Because quantum dots can change the color of the light emitted by a light source, they can be widely used in display devices, such as liquid crystal displays (LCD).

The conventional barrier film, for protecting the quantum dot layer, is made by sputtering by expensive vacuum equipment. Furthermore, there is often a problem with adhesion between the surface of the quantum dot layer and the surface of the conventional barrier film that needs a surface adhesion treatment.

Since quantum dots are more sensitive to water and oxygen molecules, most of them are equipped with expensive optical grade oxygen barrier moisture barrier films containing inorganic materials. However, these types of barrier films still account for the highest cost structure of the quantum dot film.

Accordingly, the present invention proposes a new solution to overcome the above-mentioned disadvantages.

### SUMMARY OF THE INVENTION

One objective of the present invention is to develop a new type of composite barrier film made of organic polymer materials, which not only meets high light-transmission performance requirements with good transmittance and stiffness but also improves the gas and moisture barrier ability, the new type of composite barrier film can be used as a substrate with good stiffness for supporting a quantum-dot layer.

In one embodiment, the present invention discloses a composite barrier film, wherein the composite barrier film comprises: a first substrate, a second substrate and a first barrier layer, wherein each of the first substrate and the second substrate comprises a first polymer material, and the first barrier layer comprises a first organic material capable of being water-resistant and oxygen-resistant, wherein the first barrier layer is disposed between the first substrate and the second substrate.

In one embodiment, the present invention discloses a composite quantum-dot optical film, wherein the composite quantum-dot optical film comprises: a quantum-dot layer, comprising a binder and a plurality of quantum dots dispersed in the binder; a first composite structure, comprising a first substrate and a second substrate, wherein each of the first substrate and the second substrate is made of a first polymer material, wherein a first barrier layer is made of a first organic material and capable of being water-resistant and oxygen-resistant is disposed between the first substrate and the second substrate, wherein the first composite structure is disposed on a top surface of the quantum-dot layer.

In one embodiment, the composite quantum-dot optical film further comprises a second composite structure comprising a third substrate and a fourth substrate, wherein each of the third substrate and the fourth substrate is made of a second polymer material, wherein a second barrier layer is made of a second organic material and is disposed between the third substrate and the fourth substrate, wherein the second composite structure is disposed on a bottom surface of the quantum-dot layer.

In one embodiment, the organic material comprises at least one of the following polymer materials capable of being oxygen-resistant: PVA (Polyvinyl alcohol), PVDC (Polyvinylidene chloride), PEI(Polyethyleneimine), EVOH (Ethylene-vinyl alcohol copolymer), BOPA (Biaxially oriented polyamide film, or at least one of the following polymer materials capable of being water-resistant: PE(polyethylene), CPP (unstretched polypropylene film), OPP (0-phenyl phenol), BOPP (Biaxially oriented polypropylene film).

In one embodiment, the organic material comprises at least one of the following polymer materials capable of being oxygen-resistant: PVA (Polyvinyl alcohol), PVDC (Polyvinylidene chloride), PEI(Polyethyleneimine), EVOH (Ethylene-vinyl alcohol copolymer), BOPA (Biaxially oriented polyamide film, and at least one of the following polymer materials capable of being water-resistant: PE(polyethylene), CPP (unstretched polypropylene film), OPP (0-phenyl phenol), BOPP (Biaxially oriented polypropylene film).

In one embodiment, the first organic material is coated on the first substrate.

In one embodiment, the second organic material is coated on the third substrate.

In one embodiment, the thickness of the first barrier layer is in the range of 50-70 um.

In one embodiment, the thickness of the second barrier layer is in the range of 50-70 um.

In one embodiment, the thickness of the first substrate made of the first polymer is in the range of 12-50 um.

In one embodiment, the thickness of the second substrate made of the second polymer is in the range of 12-50 um.

In one embodiment, the thickness of the first substrate made of the first polymer is in the range of 12-50 um.

In one embodiment, the thickness of the second substrate made of the second polymer is in the range of 12-50 um.

In one embodiment, the thickness of the quantum-dot layer is in the range of 150-300 um.

In one embodiment, a plurality of diffusion particles are dispersed in the binder, wherein the plurality of diffusion particles comprise organic particles, and a concentration of the plurality of diffusion particles in the binder is 2 to 40 wt %.

In one embodiment, the quantum dots comprise cadmium (Cd), wherein the concentration of the Cd is 0.1 to 20 wt %.

In one embodiment, the quantum dots comprise cadmium (Cd), wherein the concentration of the Cd is 0.3 to 8 wt %.

In one embodiment, the present invention discloses a method to form a composite barrier film, wherein the method comprises: coating an organic material on a first substrate, wherein the organic material is capable of water-resistant and oxygen-resistant; attaching the coated first organic material with a second substrate, wherein the coated first organic material is disposed between the first substrate and the second substrate.

In one embodiment, the quantum-dot layer further comprises a plurality of diffusing particles dispersed in the binder.

In one embodiment, the binder comprises PET (polyethylene terephthalate).

In one embodiment, the present invention discloses a method to form a composite quantum-dot optical film, the method comprising: coating an organic material on a first substrate, wherein the organic material is capable of being water-resistant and oxygen-resistant; attaching the coated first organic material with a second substrate to form a first composite structure, wherein the coated first organic material is disposed between the first substrate and the second substrate; and attaching the first composite structure with a quantum-dot layer comprising a binder and a plurality of quantum dots dispersed in the binder.

The detailed technology and above preferred embodiments implemented for the present invention are described in the following paragraphs accompanying the appended drawings for people skilled in this field to well appreciate the features of the claimed invention.

### BRIEF DESCRIPTION OF THE DRAWINGS

The foregoing aspects and many of the accompanying advantages of this invention will become more readily appreciated as the same becomes better understood by reference to the following detailed description when taken in conjunction with the accompanying drawings, wherein:

FIG. 1 shows a side view of a composite quantum-dot optical film according to one embodiment of the present invention;

FIG. 2A shows a method to form a composite barrier film;

FIG. 2B shows a schematic side view of step 201 in FIG. 2 according to one embodiment of the present invention;

FIG. 2C shows a schematic side view of step 202 in FIG. 2 according to one embodiment of the present invention;

FIG. 2D shows a method to form a composite barrier film;

FIG. 3A shows a method to form a composite barrier film;

FIG. 3B shows a method to form a composite barrier film;

FIG. 3C shows a method to form a composite barrier film;

FIG. 3D shows a method to form a composite barrier film;

FIG. 3E shows a side view of a composite barrier film;

FIG. 3F shows a side view of a composite quantum-dot optical film; and

FIG. 4 shows a chart to compare the OTR (Oxygen transmission rate) of the present invention with the traditional method.

### DETAILED DESCRIPTION OF THE ILLUSTRATED EMBODIMENTS

The detailed explanation of the present invention is described as follows. The described preferred embodiments are presented for purposes of illustrations and descriptions, and they are not intended to limit the scope of the present invention.

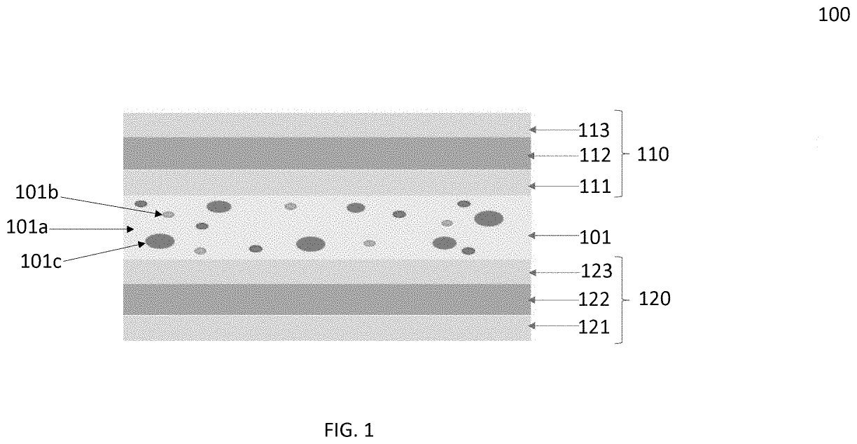

FIG. 1 shows a side view of a composite quantum-dot optical film 100 according to one embodiment of the present invention, wherein composite quantum-dot optical film 100 comprises: a quantum-dot layer 101 comprising a binder 101a and a plurality of quantum dots 101b dispersed in the binder 101a; a first composite structure 110, comprising a first substrate 111 and a second substrate 113, wherein each of the first substrate 111 and the second substrate 113 comprising a first polymer material, wherein a first barrier layer 112 comprising a first organic material and being capable of being water-resistant and oxygen-resistant is disposed between the first substrate 111 and the second substrate 113, wherein the first composite structure 110 is disposed on a top surface of the quantum-dot layer 101.

In one embodiment, the composite quantum-dot optical film 100 further comprises a second composite structure 120 comprising a third substrate 121 and a fourth substrate 123, wherein each of the third substrate 121 and the fourth substrate 123 comprises a second polymer material, wherein a second barrier layer 122 comprising a second organic material is disposed between the third substrate 121 and the fourth substrate 123, wherein the second composite structure 120 is disposed on a bottom surface of the quantum-dot layer 101.

In one embodiment, the organic material comprises at least one of the following materials capable of being oxygen-resistant: PVA (Polyvinyl alcohol), PVDC (Polyvinylidene chloride), AC, EVOH (Ethylene vinyl alcohol), BOPA (Biaxially oriented polyamide), or at least one of the following materials capable of being water-resistant: PE(polyethylene), CPP (Cast Polypropylene), OPP (Oriented Polypropylene), BOPP (Biaxially Oriented Polypropylene).

In one embodiment, the organic material comprises at least one of the following materials capable of being oxygen-resistant: PVA (Polyvinyl alcohol), PVDC (Polyvinylidene chloride), AC, EVOH (Ethylene vinyl alcohol), BOPA (Biaxially oriented polyamide), and at least one of the following materials capable of being water-resistant: PE(polyethylene), CPP (Cast Polypropylene), OPP (Oriented Polypropylene), BOPP (Biaxially Oriented Polypropylene).

In one embodiment, the first organic material is coated on the first substrate.

In one embodiment, the second organic material is coated on the third substrate.

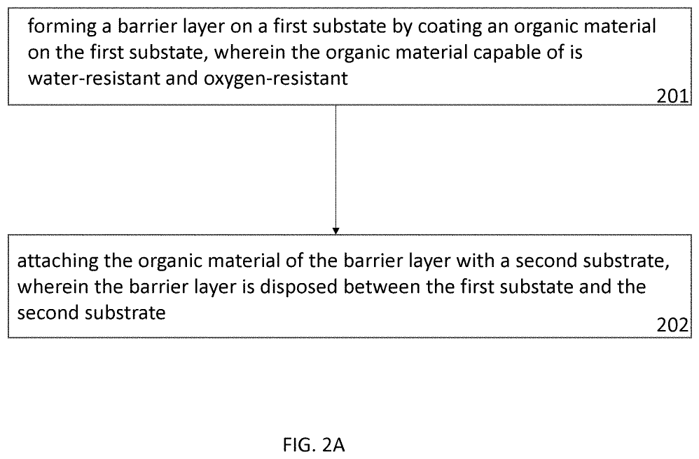

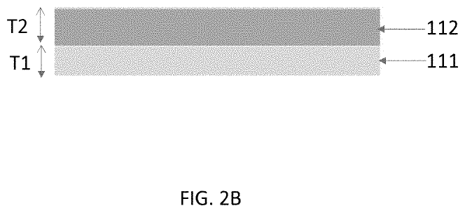

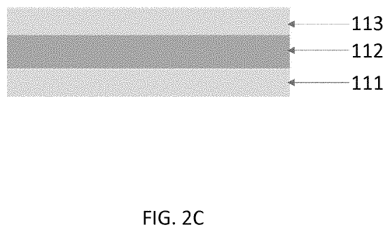

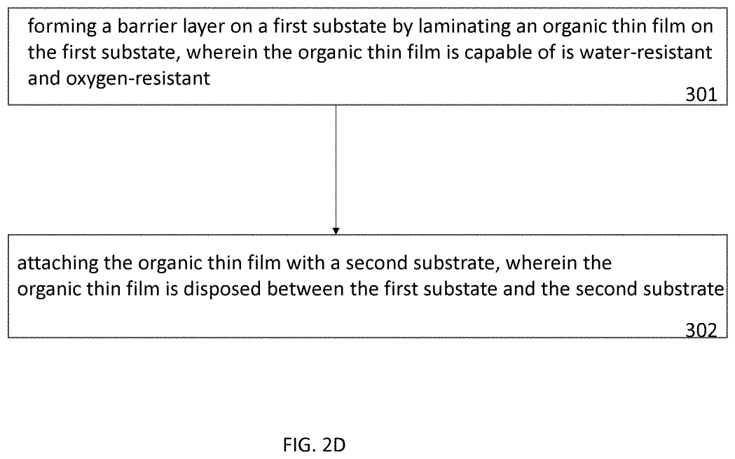

In one embodiment, as shown in FIG. 2B, the thickness T2 of the first barrier layer is in the range of 50-70 um.

In one embodiment, the thickness of the second barrier layer is in the range of 50-70 um.

In one embodiment, as shown in FIG. 2B, the thickness T1 of the first substrate made of the first polymer is in the range of 12-50 um.

In one embodiment, the thickness of the second substrate made of the second polymer is in the range of 12-50 um.

In one embodiment, the thickness of the quantum-dot layer is in the range of 150-300 um.

In one embodiment, as shown in FIG. 1A, a plurality of diffusion particles 101c, are dispersed in the binder 101a, wherein the plurality of diffusion particles 101c comprise organic particles, and a concentration of the plurality of diffusion particles in the binder is 2 to 40 wt %.

In one embodiment, the first polymer comprises an acrylic resin.

In one embodiment, the second polymer comprises an acrylic resin.

In one embodiment, the acrylic resin comprises a monomer (Monomer) type.

In one embodiment, the acrylic resin comprises a multi-body (Oligomer) type.

In one embodiment, the first substrate 211 comprises at least one of the following materials: PET (polyethylene terephthalate), PEN (polyethylene naphtholate), PAR (polyacrylate), PC (polycarbonates), or TAC (cellulose triacetate).

In one embodiment, the second substrate 311 comprises at least one of the following materials: PET (polyethylene terephthalate), PEN (polyethylene naphtholate), PAR (polyacrylate), PC (polycarbonates), or TAC (cellulose triacetate).

In one embodiment, the binder 101a of the quantum-dot layer 101 comprises at least one of the following materials: PET (polyethylene terephthalate), PEN (polyethylene naphtholate), PAR (polyacrylate), PC (polycarbonates), or TAC (cellulose triacetate).

In one embodiment, the binder 101a of the quantum-dot layer 101 comprises at least one of the following materials: PET (polyethylene terephthalate), PEN (polyethylene naphtholate), PAR (polyacrylate), PC (polycarbonates), or TAC (cellulose triacetate).

In one embodiment, the diffusion particles can be organic particles, such as PMMA, PS, Melamine, etc., or inorganic particles, such as Silicon, SiO2, TiO2, CaCO3, Al2O3, ZrO2, etc. The concentration can be from 2 to 40%, and the best is 5-15%.

In one embodiment, the quantum dots comprise cadmium (Cd), wherein the concentration of the Cd is 0.1 to 20 wt %.

In one embodiment, the quantum dots comprise cadmium (Cd), wherein the concentration of the Cd is 0.3 to 8 wt %.

FIG. 2A shows a method to form a composite barrier film, wherein the method comprises: step 201: forming a barrier layer 112 on a first substrate 111 by coating an organic material on the first substrate 111, as shown in FIG. 2B, wherein the organic material is capable of being water-resistant and oxygen-resistant; and step 202: attaching the organic material of the barrier layer 111 with a second substrate 113, wherein the barrier layer 112 is disposed between the first substrate 111 and the second substrate 113, as shown in FIG. 2C.

In one embodiment, the diffusion particles comprise organic particles, wherein. the concentration of the diffusion particles is 2 to 40 wt %.

In one embodiment, the diffusion particles comprise organic particles, wherein. the concentration of the diffusion particles is 5-15 wt %.

In one embodiment, the first polymer comprises an acrylic resin.

In one embodiment, the second polymer comprises an acrylic resin.

In one embodiment, the acrylic resin comprises a monomer (Monomer) type.

In one embodiment, the acrylic resin comprises a multi-body (Oligomer) type.

In one embodiment, the binder 201B of the quantum-dot layer 201 comprises PET (polyethylene terephthalate).

In one embodiment, the plurality of quantum dots 201A comprises red quantum dots and green quantum dots.

FIG. 2D shows a method to form a composite barrier film, wherein the method comprises: step 301: forming a barrier layer on a first substrate by laminating an organic thin film on the first substrate, wherein the organic thin film is capable of water-resistant and oxygen-resistant; and step 302: attaching the organic thin film with a second substrate, wherein the organic thin film is disposed between the first substrate and the second substrate.

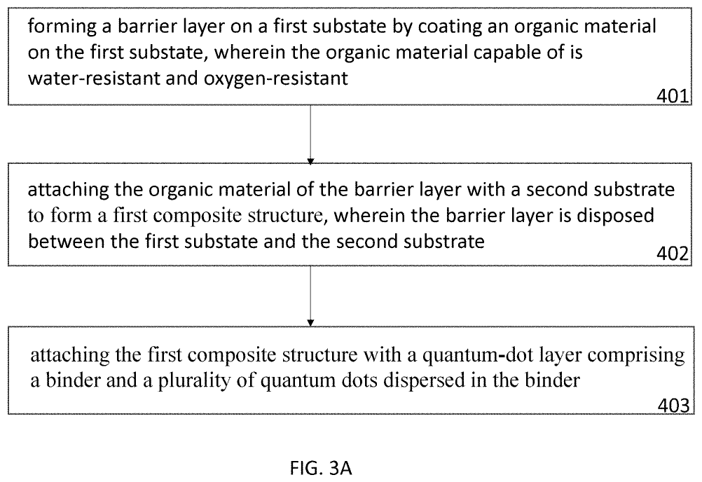

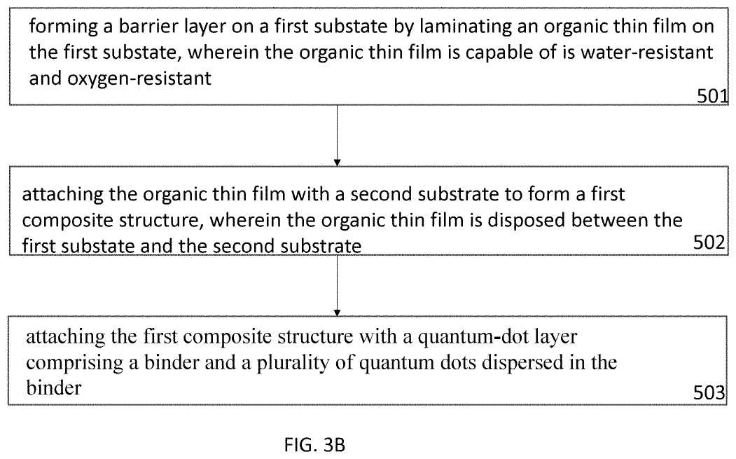

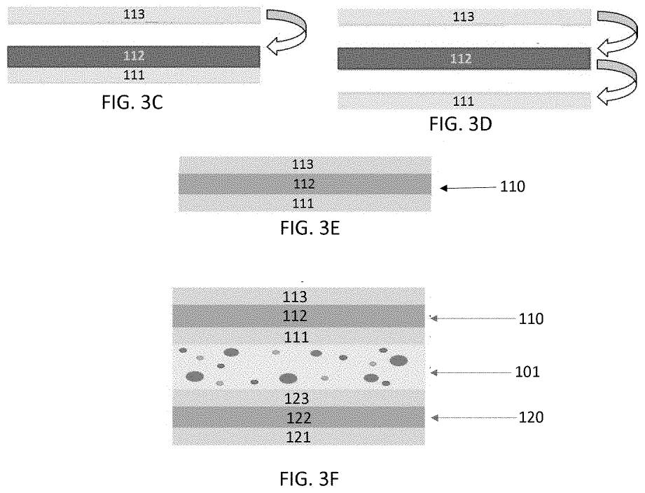

In one embodiment, as shown in FIG. 3A, the present invention discloses a method to form a composite quantum-dot optical film, the method comprising: step 401: coating an organic material on a first substrate 111 to form a barrier layer 112 on the first substrate 112, wherein the organic material is capable of being water-resistant and oxygen-resistant; step 402: attaching the coated first organic material of the barrier layer 112 with a second substrate 113 to form a first composite structure 110, wherein the coated first organic material of the barrier layer 112 is disposed between the first substrate 111 and the second substrate 113, as shown in FIG. 3C and FIG. 3E; and step 403: attaching the first composite structure 110 with a quantum-dot layer 101 comprising a binder and a plurality of quantum dots dispersed in the binder, as shown in FIG. 3F.

In one embodiment, a quantum-dots dispensing solution is coated on the lower composite structure 120 to form the quantum-dot layer, and at the same time, the upper composite structure 110 is laminated on the quantum-dot layer by a roll-to-roll laminating process.

In one embodiment, as shown in FIG. 3B, the present invention discloses a method to form a composite quantum-dot optical film, wherein the method comprises: step 501: forming a barrier layer 112 on a first substrate 111 by laminating an organic thin film on the first substrate 111, wherein the organic thin film of the barrier layer 112 is capable of water-resistant and oxygen-resistant; step 502: attaching the organic thin film with a second substrate to form a first composite structure, wherein the organic thin film of the barrier layer 112 is disposed between the first substrate 111 and the second substrate 113, as shown in FIG. 3D and FIG. 3E; and step 503: attaching the first composite structure with a quantum-dot layer comprising a binder and a plurality of quantum dots dispersed in the binder, as shown in FIG. 3F.

In one embodiment, a quantum-dots dispensing solution is coated on the lower composite structure 120 to form the quantum-dot layer, and at the same time, the upper composite structure is laminated on the quantum-dot layer by a roll-to-roll laminating process.

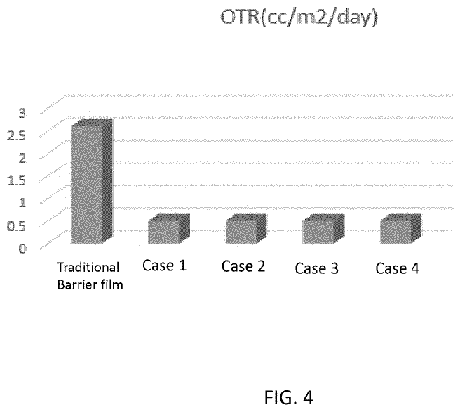

FIG. 4 shows a chart to compare the OTR (Oxygen transmission rate) of the present invention with the traditional method, wherein cases 1-4 represent the composite barrier film of the present invention with different organic materials having barrier capability, and Y-axis represents the OTR (Oxygen transmission rate) of the barrier film structures, wherein the organic material having barrier capability comprises CPP/PE in case 1, CPP/BOPA in case 2, BOPP/BOPA in case 3, and BOPP/PVA in case 4. As shown in FIG. 4, the OTR (Oxygen transmission rate) of the traditional barrier film can be as high as 2.5, and in cases 1-4 of the present invention, the OTR (Oxygen transmission rate) is as low as 0.5.

The advantages of the present invention include: 1. organic materials with different properties can be applied to the polymer substrate film through the coating or lamination process to form a composite film as a substrate with gas or moisture barrier capability to improve the reliability and stability of the quantum dot optical film; 2. the composite film is compatible with the mechanical properties and light transmittance of the original polymer substrate, and the original polymer substrate can also be customized and processed to obtain high light-extraction efficiency of the quantum dot film; 3. this type of gas barrier and moisture barrier composite membrane has the advantages of low cost and good for green environment.

The above disclosure is related to the detailed technical contents and inventive features thereof. People skilled in this field may proceed with a variety of modifications and replacements based on the disclosures and suggestions of the invention as described without departing from the characteristics thereof. Nevertheless, although such modifications and replacements are not fully disclosed in the above descriptions, they have substantially been covered in the following claims as appended.

What is claimed is:

1. A composite quantum-dot optical film comprising:
a quantum-dot layer, comprising a binder and a plurality of quantum dots dispersed in the binder;
a first composite structure, comprising a first substrate and a second substrate, and a first barrier layer, wherein each of the first substrate and the second substrate comprises a first polymer material, wherein the first barrier layer is made of a first organic material and capable of being water-resistant and oxygen-resistant, wherein the first barrier layer is disposed between the first substrate and the second substrate;
wherein the first composite structure is disposed on a top surface of the quantum-dot layer.

2. The composite quantum-dot optical film according to claim 1, further comprising a second composite structure comprising a third substrate and a fourth substrate, wherein each of the third substrate and the fourth substrate comprises a second polymer material, wherein a second barrier layer is made of a second organic material and capable of being water-resistant and oxygen-resistant, wherein the second barrier layer is disposed between the third substrate and the fourth substrate, wherein the second composite structure is disposed on a bottom surface of the quantum-dot layer.

3. The composite quantum-dot optical film according to claim 1, wherein the organic material comprises at least one of the following materials capable of being oxygen-resistant: PVA, PVDC, AC, EVOH, BOPA, or at least one of the following materials capable of being water-resistant: PE, CPP, OPP, BOPP.

4. The composite quantum-dot optical film according to claim 1, wherein the first substrate comprises at least one of the following materials: PET (polyethylene terephthalate), PEN (polyethylene naphtholate), PAR (polyacrylate), PC (polycarbonates), or TAC (cellulose triacetate).

5. The composite quantum-dot optical film according to claim 2, wherein the second substrate comprises at least one of the following materials: PET (polyethylene terephthalate), PEN (polyethylene naphtholate), PAR (polyacrylate), PC (polycarbonates), or TAC (cellulose triacetate).

6. The composite quantum-dot optical film according to claim 1, wherein the first organic material is coated on the first substrate.

7. The composite quantum-dot optical film according to claim 1, wherein the second organic material is coated on the third substrate.

8. The composite quantum-dot optical film according to claim 1, wherein a thickness of the first substrate made of the first polymer material is in a range of 12-50 um, and a thickness of the first barrier layer is in a range of 50-70 um.

9. The composite quantum-dot optical film according to claim 2, wherein a thickness of the second substrate made of the second polymer material is in a range of 12-50 um, and a thickness of the second barrier layer is in a range of 50-70 um.

10. The composite quantum-dot optical film according to claim 2, wherein a thickness of the quantum-dot layer is in a range of 150-300 um.

11. The composite quantum-dot optical film according to claim 1, wherein a plurality of diffusion particles are dispersed in the binder, wherein the plurality of diffusion particles comprise organic particles, and a concentration of the plurality of diffusion particles in the binder is 2 to 40 wt %.

12. The composite quantum-dot optical film according to claim 1, wherein the quantum dots comprise cadmium (Cd), wherein the concentration of the Cd is 0.1 to 20 wt %.

13. The composite quantum-dot optical film according to claim 1, wherein the quantum dots comprise cadmium (Cd), wherein the concentration of the Cd is 0.3 to 8 wt %.

14. The composite quantum-dot optical film according to claim 1, wherein the first polymer comprises an acrylic resin.

15. A method to form a composite quantum-dot optical film, the method comprising:
coating an organic material on a first substrate, wherein the organic material is capable of being water-resistant and oxygen-resistant;
attaching the coated first organic material with a second substrate to form a first composite structure, wherein the coated first organic material is disposed between the first substrate and the second substrate; and
attaching the first composite structure with a quantum-dot layer comprising a binder and a plurality of quantum dots dispersed in the binder.

16. The method according to claim 15, wherein the organic material comprises at least one of the following materials capable of being oxygen-resistant: PVA, PVDC, AC, EVOH, BOPA, and at least one of the following materials capable of being water-resistant: PE, CPP, OPP, BOPP.

17. The method according to claim 15, further comprising: attaching a second composite structure with the quantum-dot layer, wherein the second composite structure comprises a third substrate and a fourth substrate, wherein each of the third substrate and the fourth substrate comprises a second polymer material, wherein a second barrier layer is made of a second organic material and capable of being water-resistant and oxygen-resistant, wherein the second barrier layer is disposed between the third substrate and the fourth substrate.

18. The method according to claim 17, wherein a thickness of the first substrate made of the first polymer material is in a range of 12-50 um, and a thickness of the first barrier layer is in a range of 50-70 um.

19. The method according to claim 15, wherein a thickness of the quantum-dot layer is in a range of 150-300 um.

20. The method according to claim 18, wherein a thickness of the second substrate made of the second polymer material is in a range of 12-50 um, and a thickness of the second barrier layer is in a range of 50-70 um.
